(19) United States
(12) Patent Application Publication
(10) Pub. No.: US 2026/0173862 A1
(43) Pub. Date: Jun. 18, 2026

(54) APPARATUS INCLUDING MIM CAPACITORS IN BEOL

(71) Applicant: MICRON TECHNOLOGY, INC., BOISE, ID (US)

(72) Inventors: Shigeru Sugioka, Hiroshima (JP); Keizo Kawakita, Higashi Hiroshima-shi (JP)

(21) Appl. No.: 19/416,490

(22) Filed: Dec. 11, 2025

Related U.S. Application Data
(60) Provisional application No. 63/733,354, filed on Dec. 12, 2024.

(51) Int. Cl. H10W 20/40; H10B 12/00; H10D 1/00; H10D 1/68

(52) U.S. Cl. CPC H10W 20/496; H10B 12/315; H10B 12/50; H10D 1/043; H10D 1/692; H10D 1/716

(57) ABSTRACT

Embodiments of the disclosure provide an apparatus comprising a plurality of metal-insulator-metal (MIM) capacitors between lower and upper metal wiring layers in a portion fabricated in a back-end-of-line (BEOL) process above a semiconductor substrate. A first MIM capacitor and a second MIM capacitor of the plurality of MIM capacitors include a first insulator of a first thickness and a second insulator of a second thickness greater than the second thickness, respectively. The first MIM capacitor may be for a first voltage. The second MIM capacitor may be for a second voltage greater than the first voltage.

### CROSS-REFERENCE TO RELATED APPLICATIONS

This application claims the filing benefit of U.S. Provisional Application No. 63/733,354, filed Dec. 12, 2024. This application is incorporated by reference herein in its entirety and for all purposes.

### BACKGROUND

A semiconductor device, such as a memory device and a logic device, may include a compensation capacitor in a portion fabricated in a back-end-of-line (BEOL) process above a semiconductor substrate. A compensation capacitor may be a metal-insulator-metal (MIM) capacitor including an insulator between an upper metal electrode and a lower metal electrode.

### BRIEF DESCRIPTION OF THE DRAWINGS

FIG. 1 depicts at least part of an example memory device in a cross-sectional view according to some embodiments of the disclosure.

FIG. 2 depicts at least part of an example apparatus in a cross-sectional view according to some embodiments of the disclosure.

FIG. 3 depicts at least part of an example apparatus in a cross-sectional view according to some embodiments of the disclosure.

FIG. 4 depicts at least part of an example apparatus in a cross-sectional view according to some embodiments of the disclosure.

FIGS. 5A-5L depict example processes of manufacturing an example apparatus in a cross-sectional view according to some embodiments of the disclosure.

FIGS. 6A-6K depict example processes of manufacturing an example apparatus in a cross-sectional view according to some embodiments of the disclosure.

FIG. 7 depicts at least part of an example apparatus in a cross-sectional view according to some embodiments of the disclosure.

FIG. 8 depicts at least part of an example apparatus in a cross-sectional view according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

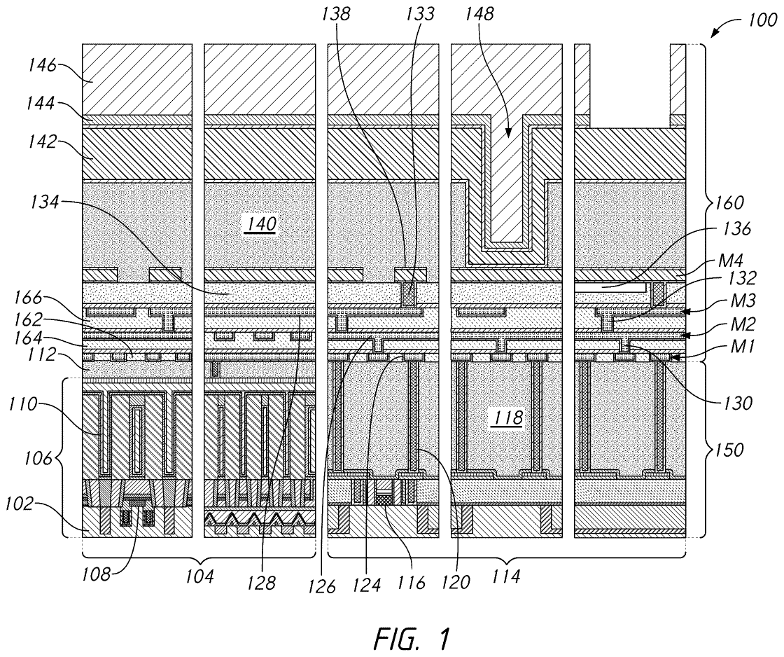

FIG. 1 depicts at least part of an example memory device 100 in a cross-sectional view according to some embodiments of the disclosure. The memory device 100 may be one example of an apparatus. The memory device 100 may be a dynamic random-access memory (DRAM). The memory device 100 may include a memory cell region 104 and a peripheral region 114. The memory device 100 may include a portion 150 fabricated in a front-end-of-line (FEOL) above a substrate 102. The portion 150 fabricated in the FEOL may include a memory cell 106 in the memory cell region 104. The memory cell 106 may be disposed on the substrate 102. The memory cell 106 may include a transistor 108 on the substrate 102 and a capacitor 110 coupled to the transistor 108. An insulating film 112 may be disposed on the substrate 102, above the capacitor 110. The substrate 102 may be a semiconductor substrate.

In the peripheral region 114, the portion fabricated in the FEOL may include a transistor 116 that may be disposed on the substrate 102. An insulating film 118 may be disposed above the substrate 102 in the peripheral region 114. The insulating film 118 may be disposed above the transistor 116. A via 120 coupled to the transistor 116 may be disposed within the insulating film 118. In some embodiments, the insulating films 112 and 118 may be continuous. In some embodiments, the insulating films 112 and 118 may include the same material, for example, silicon dioxide (SiO2).

The memory device 100 may include a portion 160 fabricated in a back-end-of-line (BEOL) above the portion 150 fabricated in the FEOL. The portion 160 fabricated in the BEOL may include a plurality of insulating films or layers, such as insulating films 162, 164, and 166 above the insulating films 112 and 118. The portion 160 may also include interconnects 124, 126 and 128 disposed above the insulating films 112 and 118. The interconnect 124 may be disposed on the insulating films 112 and 118. The interconnect 126 may be disposed on one or more insulating films above the interconnect 124. The interconnect 128 may be disposed on one or more insulating films above the interconnect 128. The portion 160 may further include one or more interconnects 130 and 132 that couple the interconnects 124, 126 and 128 to one another in a vertical direction. In some embodiments, the interconnects 130 and 132 may include the same material as the interconnects 124, 126 and 128. The portion 160 may further include one or more insulating films or layers on the interconnect 128. In some embodiments, the interconnects 124, 126 and 128 may be part of or included in conductive layers. In some embodiments, the interconnects 124, 126 and 128 may be part of or included in a first metal layer (which may be referred to as M1), a second metal layer (which may be referred to as M2), and a third metal layer (which may be referred to as M3), respectively. The interconnects 124, 126 and 128 each may include metal, such as copper (Cu). In some embodiments, the insulating films 162, 164, and 166 of the portion 160 each may include a low-k material. The low-k material may have a lower dielectric constant (k) than silicon dioxide (SiO2) that exhibits weak electric polarization between conductive layers. The low-k material may be included to prevent diffusion of a conductive material, such as copper (Cu), and to reduce parasitic capacitance between the interconnects. Using the low-k material may help to achieve high speed operations of electronic circuits in the semiconductor devices. In some embodiment, the low-k material may include silicon oxycarbide (SiOC) or silicon carbonitride (SiCN). In some embodiments, the interconnects 124, 126, 128, 130 and 132 may include coating on surfaces in contact with the low-k material.

An insulating film 134 may be disposed above the interconnects 128. The insulating film 134 may include an oxide material, such as silicon dioxide (SiO2). Within the insulating film 134, a capacitor 136 may be disposed. In some embodiments, the capacitor 136 may be a metal-insulator-metal (MIM) capacitor. Above the insulating film 134 and the capacitor 136, another interconnect 138 may be disposed. In some embodiments, the interconnect 138 may be part of or included in a conductive layer, such as a fourth metal layer (which may be referred to as M4) above the third metal layer (M3). The interconnect 138 may include metal, such as aluminum (Al). In some embodiment, the interconnect 138 or the conductive layer may be an integrated redistribution layer (iRDL). The capacitor 136 in the insulating film 134 may be coupled to the interconnect 138. In some embodiments, there may be one or more insulating films disposed above and/or below the insulating film 134. The portion 160 may further include one or more interconnects 133 in the insulating film 134 that couple the interconnects 128 and 138 in a vertical direction. The interconnects 133 may include the same material as the interconnects 130 and 132. The portion 160 may include another insulating layer 140 on the interconnect 138. The insulating layer 140 may include an oxide material, such as silicon dioxide (SiO2). The insulating layer 140 may have an opening 148. A conductive layer 142 may be disposed above the insulating layer 140. The conductive layer 142 may have a portion covering the insulating layer 140 along a side of the opening 148 and a portion that is a bottom of the opening 148 where a pad may be disposed to be coupled to the interconnect 138 The conductive layer 142 may include metal, such as aluminum (Al). In some embodiments, the conductive layer 142 may be covered by a passivation film 144. The passivation film 144 may include, for example, silicon nitride (Si3N4). In some embodiments, a polyimide film 146 may be disposed above the passivation film 144. The polyimide film 146 may include, for example, photopolymer material.

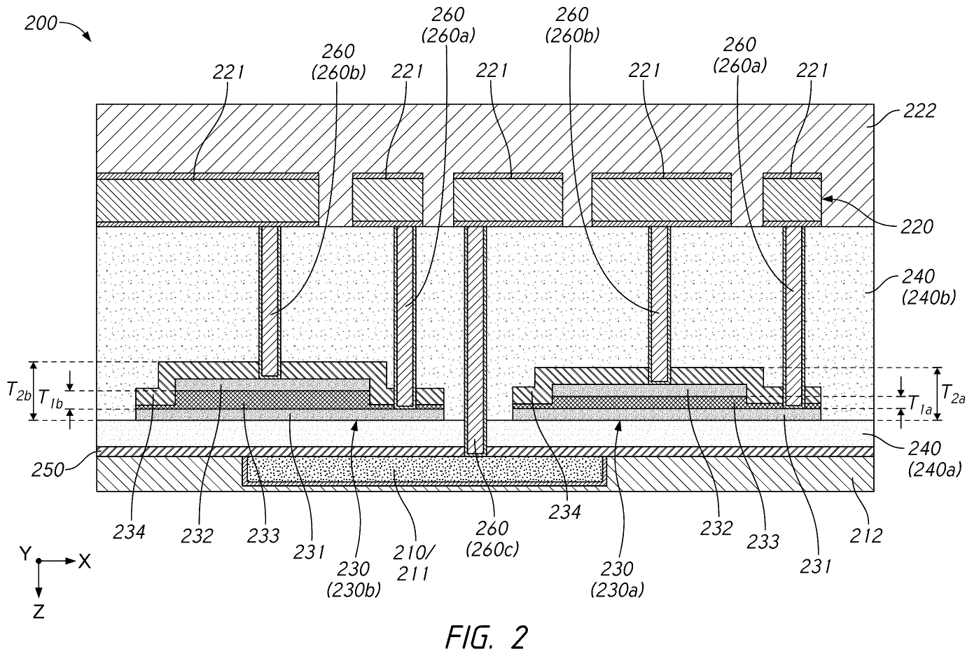

FIG. 2 depicts at least part of an example apparatus 200 in a cross-sectional view according to some embodiments of the disclosure. The apparatus 200 may be a memory device, such as a dynamic random-access memory (DRAM). The apparatus 200 may be a logic device. In the present embodiments, the apparatus 200 includes a first metal layer 210 including a plurality of first wirings 211, a second metal layer 220 including a plurality of second wirings 221 above the first metal layer 210, and a plurality of metal-insulator-metal (MIM) capacitors 230 between the first metal layer 210 and the second metal layer 220.

The apparatus 200 may include a portion fabricated in a back-end-of-line (BEOL) above a portion fabricated in a front-end-of line (FEOL) on a semiconductor substrate. The first and second metal layers 210 and 220 and the MIM capacitors 230 may be in the BEOL portion. The first and second metal layers 210 and 220 may be lower and upper wiring layers in the BEOL portion, respectively. The BEOL portion may include three or more metal/wiring layers, one of which may be the first metal layer 210 and another of which may be the second metal layer 220 above the first metal layer 210. The apparatus 200 may further include an insulating layer 240 between the first and second metal layers 210 and 220. The insulating layer 240 may be an interlayer insulating film. The insulating layer 240 may include an oxide material, such as silicon dioxide (SiO2). In the case of the apparatus 200 being a memory device, as one example, the first and second metal layers 210 and 220 may correspond to the metal layers M3 and M4 in FIG. 1, respectively, and the insulating layer 240 may correspond to the insulating film 134 in FIG. 1. The first metal wirings 211 and the second metal wirings 221 may include metal, such as copper (Cu), and in the case of a memory device, as one example, may correspond to the interconnects 128 and 138 in FIG. 1, respectively. The first metal wirings 211 and the second metal wirings 221 may be surrounded by or embedded in an insulating material 212, such as a low-k material, and an insulating material 222, such as an oxide material, respectively. The insulating materials 212 and 222 may correspond to, as one example, the insulating films 166 and 140 in FIG. 1, respectively. The apparatus 200 may further include a barrier film 250 between the first metal layer 210 and the insulating film 240 to prevent or mitigate diffusion of a conductive material, such as copper (Cu), from for example the metal wirings 211. The insulating film 240 may include a low-k material, such as silicon oxycarbide (SiOC) and silicon carbonitride (SiCN). The configuration of the BEOL portion of the memory device 100 or the apparatus 200 is not limited to the depicted examples, and the first and second metal layers 210 and 220 may be any lower and upper layers, respectively, in a BEOL portion of a memory device or a logic device as appropriate.

The MIM capacitors 230 are arranged in the insulating film 240 between the first and second metal layers 210 and 220. In the depicted example, the insulating film/layer 240 includes a first part 240a on the barrier film 250 and a second part 240b layered on the first part 240a, and the MIM capacitors 230 are arranged in the second part 240b above the first part 240a. The depicted example shows two MIM capacitors 230; however, the number of MIM capacitors 230 is not limited thereto, and may be determined based on device specification, device design, or the like. Each of the MIM capacitors 230 includes a first metal film (or a lower metal film) 231, a second metal film (or an upper metal film) 232 above the first metal film 231, and an insulating film 233 between the first metal film 231 and the second metal film 232. The first metal film 231 may be a lower electrode. The second metal film 232 may be an upper electrode. The first and second metal films 231 and 232 each may include metal, such as a titanium nitride (TiN). The first and second metal films 231 and 232 each may include a single film of TiN or a layered film of TiN and another metal material, such as tungsten (W). The insulating film 233 may be an insulting dielectric film. The insulating film 233 may be a high-k film including a high-k dielectric material. The high-k film may include an oxide film of zirconium (Zr), hafnium (Hf) or aluminum (Al), or a layered film thereof. In the present embodiments, each of the MIM capacitors 230 may also include a barrier film 234. The barrier film 234 may be provided at least on an upper surface of the MIM capacitor 230. The barrier film 234 may prevent or mitigate diffusion of metal of the metal films. The barrier film 234 may also be used as a stopper film during formation of vias 260 (which will be described in detail below). The barrier film 234 may include a low-k film, such as an SiCN film, or a high-k film, such as an aluminum oxynitride (AlON) film and an aluminum oxygen-carbon-nitride (AlOCN) film.

The apparatus 200 may further include vias 260 as vertical interconnects or contacts between each of the MIM capacitors 230 and the second/upper metal layer 220. The vias 260 extend in a vertical direction through the insulating film 240 between the MIM capacitors 203 and the second/upper metal layer 220. The vias 260 may include at least a first via 260a coupling the first metal film 231 (as the lower electrode) of the MIM capacitor 230 to a corresponding wiring 221 in the second/upper metal layer 220 and a second via 260b coupling the second metal film 232 (as the upper electrode) of the MIM capacitor 230 to a corresponding wiring 221 in the second/upper metal layer 220. The apparatus 200 may still further include one or more vias 260c coupling the first/lower metal layer 210 and the second/upper metal layer 220. The vias 260c each extend in a vertical direction through the insulating film 240. In the depicted example, both the lower electrode and the upper electrode of each of the MIM capacitors 230 receives the vias 260 from the above, that is from the upper metal layer 220. In other embodiments, the lower electrode may be coupled to a corresponding wiring in the lower metal layer 210 by one or more vias extending below the lower electrode.

In the present embodiments, the insulating film 233 of one (denoted as 230b) of the MIM capacitors 230 has a thickness greater than that of the insulating film 233 of another one (denoted as 230a) of the MIM capacitors 230. The thickness of the insulating film 233 of the MIM capacitor 230a is denoted as T1a, and the thickness of the insulating film 233 of the MIM capacitor 230b is denoted as T1b in FIG. 2. Hence, in FIG. 2, T1b>T1a. T1a may be, for example, 5-6 nm. T1b may be, for example, 8-9 nm. Accordingly, the MIM capacitors 230a and 230b have different types of insulator or capacitance film between lower and upper electrodes. This allows, for example, arranging capacitors with different requirements in the same layer or the same portion fabricated by the BEOL process. The MIM capacitor 230a including the insulating film 233 of the thickness T1a may be for a first voltage, and the MIM capacitor 230b including the insulating film 233 of the thickness T1b (T1b>T1a) may be for a second voltage greater than the first voltage. In some embodiments, the first voltage may be, for example, 0.9V, and the second voltage may be, for example, 1.8V. In the depicted example of FIG. 2, the MIM capacitor 230a and the MIM capacitor 230b are arranged in a first horizontal direction (e.g., an x-axis direction in the drawing) between the first and second metal layers 210 and 220. The MIM capacitor 230a and the MIM capacitor 230b may be arranged in series in the x-axis direction. The MIM capacitor 230a and the MIM capacitor 230b are arranged at the same or substantially the same height position between the first and second metal layers 210 and 220 in a vertical direction (e.g., a z-axis direction in the drawing). In other words, the MIM capacitors 230a and 230b are provided in a same (sub-)layer level between the lower and metal wiring layers 210 and 220. Due to the different thickness of the insulating film 233, the total thickness T1b of the MIM capacitor 230b may be greater than the total thickness T1a of the MIM capacitor 230a. In some embodiments, the total thickness T1b of the MIM capacitor 230b may be made equal to the total thickness T1a of the MIM capacitor 230a by adjusting a thickness of the first metal film 231 and/or the second metal film 232.

In recent years, with the high speed operation of a large-scale (LSI) device, and the low voltage of a complementary metal-oxide semiconductor (CMOS) device, large compensation capacitance has become important as a noise countermeasure. Some logic devices or memory devices may be equipped with a MIM capacitor in the portion fabricated by the BEOL process. In the case where a MIM capacitor uses only one type of capacitance insulation film, the insulation film thickness may be set to withstand the highest voltage (for example, a couple to a few voltages, such 1.8V) used in the device, and this may result in small capacitance. If a thin film is used to achieve large capacitance, capacitors in two or more series may be required to withstand high voltage, and there is a possibility that the area for placing such capacitors in the device is insufficient. However, according to the present embodiments, by using two or more types of insulating film for MIM capacitors, such as the MIM capacitor 230a and 230b, it is possible to include in one device, such as a logic device and a memory device, for example, a capacitor designed for a lower voltage and a higher capacitance and a capacitor designed for a higher voltage. Furthermore, by including capacitors with different requirements in one device, all capacitors may be arranged in a single series, and this reduces the die area. In the example of FIG. 2, the MIM capacitor 230a with the thinner insulating film 232 of T1a may be a capacitor suitable for a lower voltage and a higher capacitance, and the MIM capacitor 230b with the thicker insulating film 232 of T1b may be a capacitor suitable for a higher voltage.

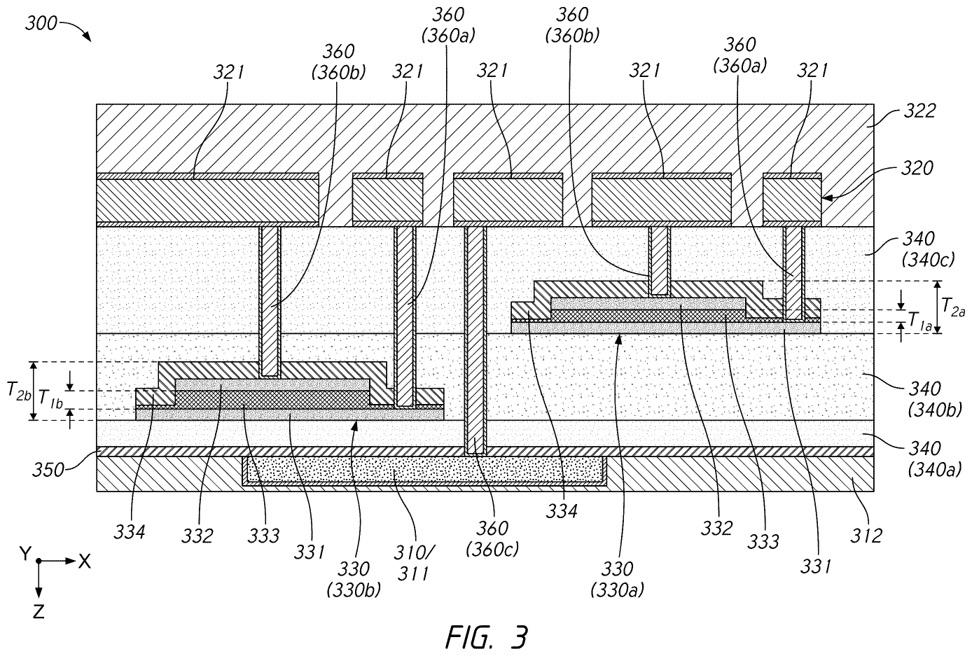

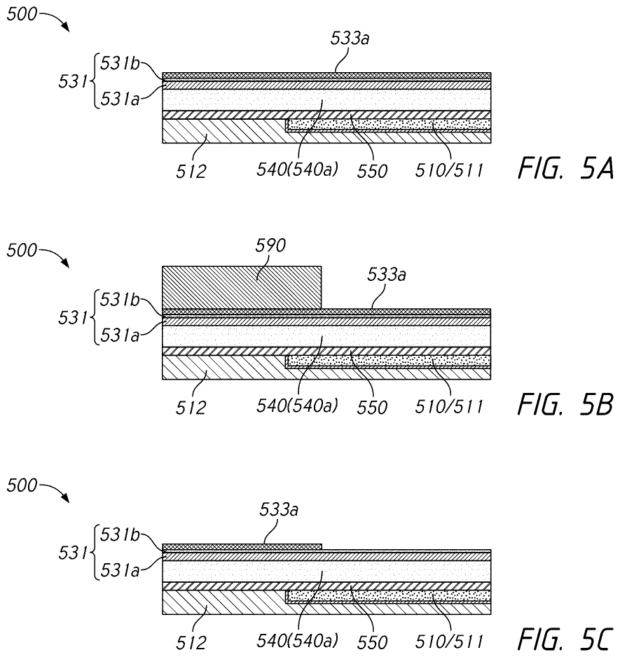

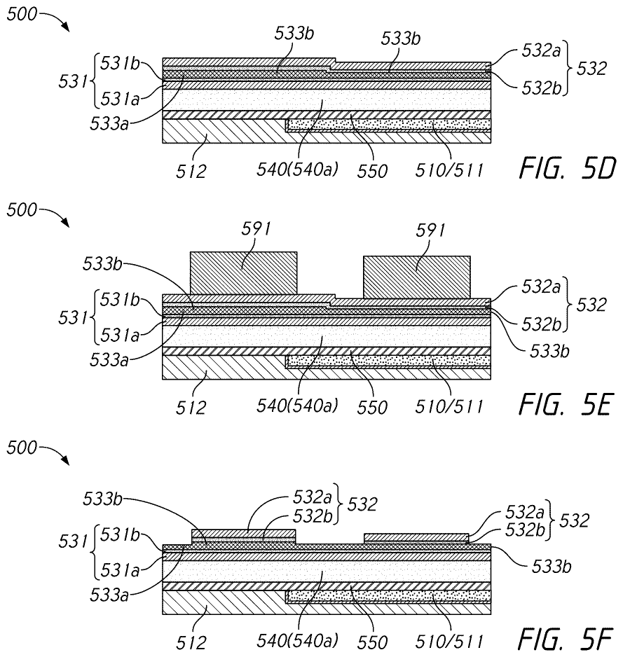

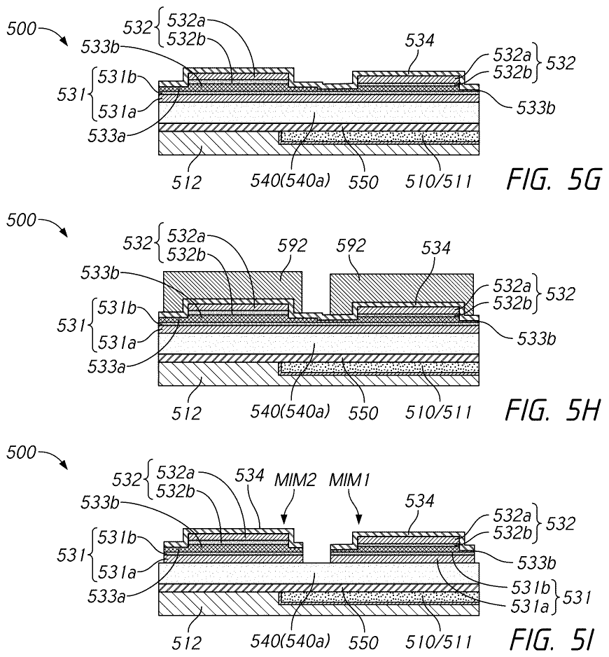

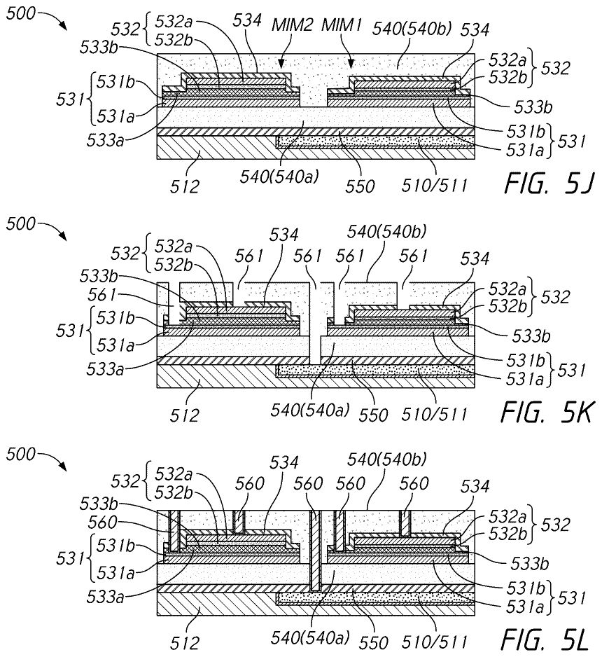

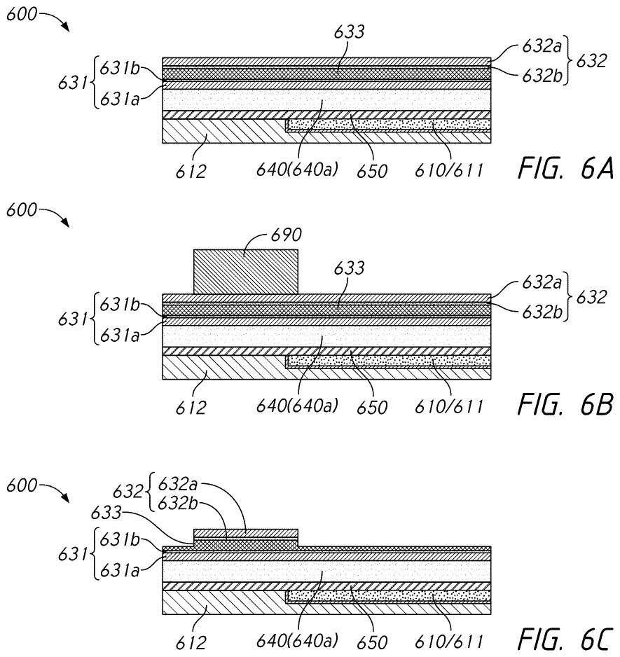

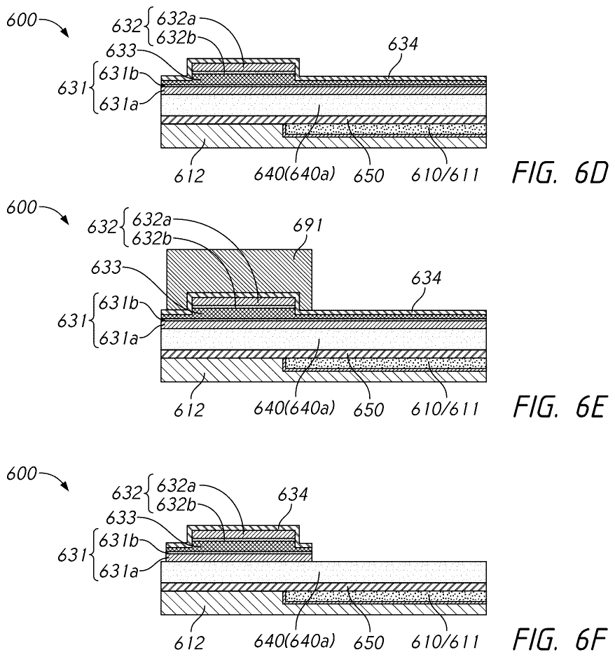

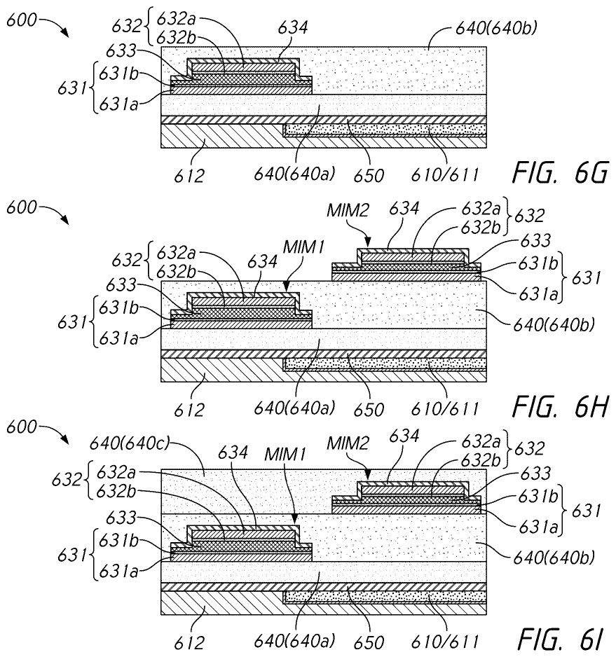

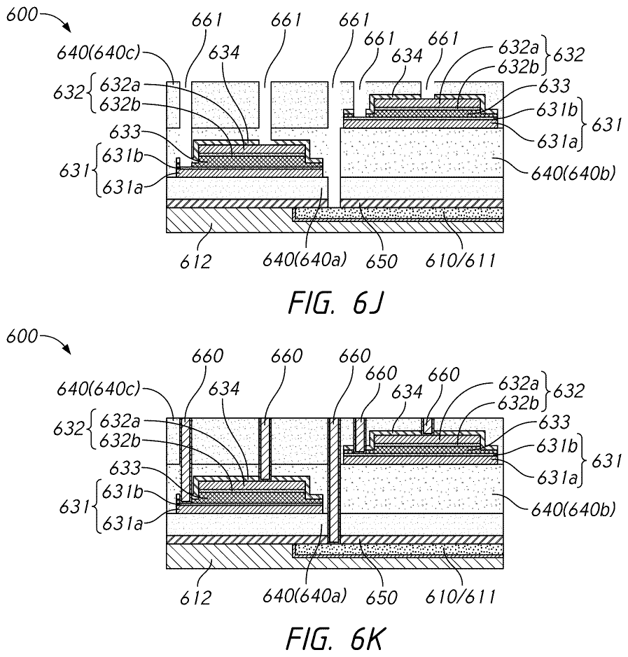

FIG. 3 depicts at least part of an example apparatus 300 in a cross-sectional view according to some embodiments of the disclosure. The apparatus 300 includes two MIM capacitors 330a and 330b which are the same or substantially the same as the MIM capacitors 230a and 230b in FIG. 2, respectively, except that the MIM capacitors 330a and 330b are arranged at a first height position and a second heigh position different from the first heigh position, respectively, in the vertical direction between first and second metal layers 310 and 320. In other words, the MIM capacitors 330a and 330b are provided in a different (sub-)layer level between lower and metal wiring layers 310 and 320. In the depicted example of FIG. 3, the MIM capacitor 330a is arranged at the first height position higher than the second height position of the MIM capacitor 330b in the z-axis direction above the first metal layer 310. In other embodiments, the MIM capacitor 330a may be positioned lower than the MIM capacitor 230b between the first and second metal layers 310 and 320. In the depicted example, the insulating film/layer 340 includes a first part 340a on the barrier film 350, a second part 340b layered on the first part 340a, and further a third part 340c layered on the second part 340b, and the lower MIM capacitor 330b is provided in the second part 340b and the upper MIM capacitor 330a is provided in the third part 340c. Some of vias 360 (360a-c) may also be adjusted according to the positions of the MIM capacitors 330a and 330b. For example, while vias 360a, 360b that couple the second metal layer 320 to the MIM capacitor 330b (the lower MIM capacitor) and to the first metal layer 310 are the same or substantially the same as the corresponding vias 260a, 260b in FIG. 2, the vias 360a, 360b that couple the second metal layer 320 to the MIM capacitor 330a (the upper MIM capacitor) are different from the corresponding vias 260a, 260b) in FIG. 2 in that the length or depth in the z-axis direction are adjusted to match the distance between the second metal layer 320 and the lower electrode and upper electrode of the upper MIM capacitor 330a. Other than the above, the configuration of the apparatus 300 is substantially the same as that of the apparatus 200, having components 310-360 (including insulating materials 312, 322, wirings 311, 321, metal films 331, 332, and insulating films 333 and barrier films 334 of MIM capacitors 330) corresponding to components 210-260, respectively, and the details thereof are omitted. Unlike the apparatus 200 including two or more MIM capacitors at the same height position which may require application and removal of a resist on and from the MIM insulator/capacitance film during fabrication (the details of which will be described below with reference to FIGS. 5A-5L; for example, see FIGS. 5A-C), the apparatus 300 including two or more MIM capacitors arranged at different height positions may not require such resist application and removal processes with respect to the MIM insulator/capacitance film during fabrication (the details of which will be described below with reference to FIGS. 6A-6K; for example, compare FIGS. 6A-6C to FIGS. 5A-5C). This prevents damage to the insulator/capacitance film during fabrication and suppresses leakage current. The apparatus 300 hence can further effectively improve reliability of the insulator/capacitance film of the MIM capacitor.

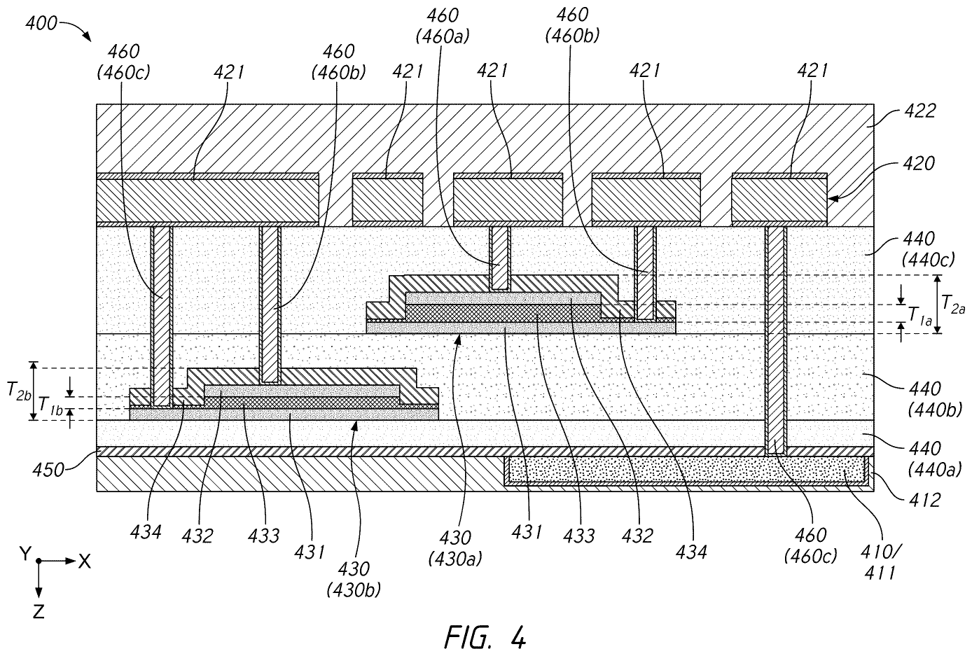

FIG. 4 depicts at least part of an example apparatus 400 in a cross-sectional view according to some embodiments of the disclosure. The apparatus 400 includes two MIM capacitors 430a and 430b which are the same or substantially the same as the MIM capacitors 230a and 230b or the MIM capacitors 330a and 330b, except that the MIM capacitors 430a and 430b are arranged at a first height position and a second heigh position different from the first heigh position, respectively, in the vertical direction between first and second metal layers 410 and 420, and the MIM capacitors 430a and 430b at least partially overlap with each other. In the depicted example of FIG. 4, the MIM capacitor 430a is arranged at the first height position higher than the second height position of the MIM capacitor 430b in the z-axis direction, and the MIM capacitor 430a is shifted in the x-axis direction towards the MIM capacitor 430b and positioned such that at least part thereof overlaps at least part of the MIM capacitor 430b at least in the x-axis direction in the drawing. The MIM capacitor 430a may also overlap the MIM capacitor 430b in another horizontal direction, e.g., a y-axis direction orthogonal to the x-axis direction in the drawing. To correspond to the positional change of the MIM capacitor 430a, some of vias 460 are also adjusted. For example, the via 460a that extends through the insulating film 440 (440c) and the barrier film 434 and couples the wiring 421 in the second metal layer 420 and the first, lower metal film 431 (as the lower electrode) of the lower MIM capacitor 430b is provided on the left side of the lower MIM capacitor 430b to avoid the overlapping portion between the upper and lower MIM capacitors 430a and 430b whereas the corresponding via 360a of the lower MIM capacitor 330b is provided on the right side of the lower MIM capacitor 330b in FIG. 3. In this arrangement, the first metal film 431 (as the lower electrode) of the lower MIM capacitor 430b is elongated more on the left side than the right side to secure the surface area where the bottom of the via 460a lands. The via 460c that extends through the insulating film 440 (440a-c) and the barrier film 450 and couples the first and second metal layers 410 and 420 is positioned to avoid the area where the MIM capacitors 430a and 430b are located. The vias 460b that extend through the insulating film 440 (440c) and the barrier film 434 and couple the wirings 421 and the second, upper metal films 432 (as the upper electrodes) of the MIM capacitors 430a, 430b may be substantially the same as those in FIG. 3, except that the position in the x-axis direction may be adjusted to correspond to the positions of the MIM capacitors 430a, 430b. In the depicted example, furthermore, the insulating film 433 of the MIM capacitor 430b is made thinner than that of the MIM capacitor 430a (T1b<T1a and T2b<T2b). That is, the thicker MIM capacitor and the thinner MIM capacitor are switched from the arrangement in FIG. 3. The thinner MIM capacitor 430b is provided at a lower position and the thicker MIM capacitor 430a is provided at a higher position whereas the thinner MIM capacitor 330a is arranged higher than the thicker MIM capacitor 330b in FIG. 3. The height positional arrangement of the thinner and thicker MIM capacitors may be determined based on device specification, device design, or the like. The length of each of the vias 360 may also be adjusted depending on the thickness of each component of each MIM capacitor. Other than the above, the configuration of the apparatus 400 is substantially the same as that of the apparatus 200 or 300, having components 410-460 (including insulating materials 412, 422) corresponding to components 210-260 or 310-360, respectively, and the details thereof are omitted. The apparatus 400 including the two or more MIM capacitors 430 at least partially overlapping each other may achieve increase in capacitance area and hence may effectively increase the amount of capacitance in total. In some embodiments, each of the overlapping MIM capacitors 430 may have its size increased in a plan (x-axis and y-axis) view, thereby increasing the capacitance area and hence the capacitance amount.

FIGS. 5A-5L depict example processes of manufacturing an example apparatus 500 in a cross-sectional view according to some embodiments of the disclosure. The apparatus 500 may correspond to the apparatus 200 in FIG. 2. Sizes, positions, and the like of the components of the apparatus 500, however, may not be the same as those of the apparatus 200. The depicted processes correspond to at least part of the BEOL process after the FEOL process. The depicted processes show providing at least two MIM capacitors in the same (sub-)layer level between lower and upper metal wiring layers.

As shown in FIG. 5A, after a barrier film 550 (e.g., 250 in FIG. 2) and an insulating film 540/540a (e.g., 240/240a in FIG. 2) are formed on an insulating layer 512 (e.g., 212 in FIG. 2) and a lower metal layer 510 (e.g., 210 in FIG. 2) including a first wiring 511 (e.g., 211 in FIG. 2) by a deposition process, a first metal film 531 (e.g., 231 in FIG. 2) that will constitute lower electrodes of MIM capacitors (e.g., 230 in FIG. 2) is formed on the insulating film 540a by another deposition process. The deposition process may be, for example, chemical vapor deposition (CVD) or physical vapor deposition (PVD). In the depicted example, the first metal film 531 includes a first film 531a such as a film of tungsten (W) and a second film 531b such as a film of titanium nitride (TiN) layered on top of each other. An insulating film 533a (e.g., 233 in FIG. 2) that will be insulators/capacitance films of MIM capacitors is then formed on the first metal film 531 by a further deposition process, such as CVD and atomic layer deposition (ALD). The insulating film 533a may include a high-k film, such as an oxide film of zirconium (Zr), hafnium (Hf) or aluminum (Al). The high-k film may include multiple layers of such high-k materials.

As shown in FIG. 5B, a resist 590 is provided as a mask on at least part of the insulating film 533a, and as shown in FIG. 5C, at least part of the insulating film 533a that is not covered by the resist 590 is removed by, for example, photolithography and dry etching. The resist 590 is stripped, and a surface is cleaned by removing by-products of stripping and dry etching by, for example, wet etching.

As shown in FIG. 5D, another insulating film 533b is formed on the exposed surface of the first metal film 531 and the insulating film 533a by, for example, CVD or ALD. The insulating film 533b may include the same high-k dielectric material as the existing insulating film 533a, such as an oxide material of Zr, Hf or Al. A second metal film 532 including a first film 532a such as a W film and a second film 532b such as a TiN film is then formed on the insulating film 533 by, for example, PVD or CVD. In the area where the initial insulating film 533a is left by the initial photolithography and dry etching, the subsequent deposition of the second insulating film 533b on the insulating film 533a forms a part with a thicker capacitance film on the left side of the drawing, and this part becomes a high-voltage MIM capacitor (e.g., 230b in FIG. 2). In the area where the capacitance film is thinner, that is the second insulating film 533b formed by the subsequent deposition on the first metal film 531 on the right side of the drawing, a low-voltage, high capacitance MIM capacitor (e.g., 230a in FIG. 2) can be formed.

Subsequently, the two MIM capacitors are separated from each other. As shown in FIG. 5E, resists 591 are provided as masks on at least part of the second metal film 532, and as shown in FIG. 5F, at least part of the second metal film 532 other than the part masked by the resists 591 are removed by, for example, photolithography and dry etching to pattern the separate upper electrodes of the two MIM capacitors. At the same time, at least part of the insulating film 533b is also removed.

As shown in FIG. 5G, a barrier film 534 (e.g., 234 in FIG. 2) is formed on the exposed surfaces of the second metal film 532 and the insulating films 533a and 533b by, for example, CVD or plasma-CVD. The barrier film 534 may prevent or mitigate metal diffusion. The barrier film 534 may also be used as an etching stop film for dry etching to form vias at a later process. The barrier film 534 may include, for example, SiCN, AlON, or AlOCN.

As shown in FIG. 5H, resists 592 are provided as masks on the barrier film 534, and as shown in FIG. 5I, at least part of the barrier film 534, at least part of the insulating films 533a and 533b, and at least part of the first metal film 531 which are not covered by the resists 592 are removed by, for example, photolithography and dry etching to pattern the separate lower electrodes of the two MIM capacitors. The resists 592 are removed and the exposed surface is cleaned by, for example, plasma ashing and/or wet etching. The two separate MIM capacitors (MIM1 and MIM2) each including the first metal film 531 as the lower electrode, the second metal film 532 as the upper electrode, and the insulating film 533 as the capacitance film between the lower and upper electrodes are thus formed on the insulating film 540 above the lower metal layer 510 including the wiring/interconnect 511.

As shown in FIG. 5J, an insulating film 540 (e.g., 340 in FIG. 2) as another interlayer insulating film 540b (e.g., 340b in FIG. 2) is formed to cover the MIM capacitors on the first interlayer insulating film 540a by, for example, CVD or plasma-CVD. The surface of the second interlayer insulating film 540b is planarized by for example chemical-mechanical polishing (CMP). The insulating film 540/540b may include an oxide material, such as SiO2.

Subsequently, vias are formed, As shown in FIG. 5K, openings 561 are formed by, for example, photolithography and dry etching. The openings 561 are provided at appropriate positions to form the vias. Some of the openings 561 may extend through the interlayer insulating film 540b and the barrier film 534 and reach the second metal film 532 (the upper electrode). Some of the openings 561 may extend through the interlayer insulating film 540b and the barrier film 534 and reach the first metal film 531 (the lower electrode). Some of the openings 561 may extend through the interlayer insulating film 540b and the interlayer insulating film 540a as well as the barrier film 550 and reach the wiring/interconnect 511 of the lower metal layer 510. As one example process, the openings 561 may be first stopped at the barrier film 534 and the barrier film 550, and then the barrier films 534 and 550 may be removed from the openings 561 at the same time. Any resist materials and by-products are removed by, for example, plasma ashing and/or wet etching to clean the surfaces of the openings 561. As shown in FIG. 5L, the openings 561 are filled with a barrier metal material and a metal material by, for example, PVD, CVD, or ALD to form the vias 560 (e.g., 260 in FIG. 2). The barrier metal material may be, for example, tungsten nitride (WN), and the metal material may be, for example, W. As one example process, a film of WN is formed on the surface of each of the openings 561 by ALD, and a film of W is then formed on the WN film by CVD. The exposed upper surfaces or top portions of the WN and W films are then removed by for example CMP. The via 560 that reaches the lower electrode of the MIM capacitor may correspond to the via 260a in FIG. 2. The via 560 that reaches the upper electrode of the MIM capacitor may correspond to the via 260b in FIG. 2. The via that reaches the lower metal layer 510 may correspond to the via 260c in FIG. 2. In other embodiments, some vias of the lower electrode may be provided from the below, coupling to the lower metal layer 510.

Finally, an upper metal wiring layer, such as 220 in FIG. 2 is formed by for example PVD, and a wiring/interconnect, such as 221 in FIG. 2, is patterned by for example photolithography and dry etching. The upper metal wiring layer may include TiN, Al, and Ti, and the wiring/interconnect may include Al. The surfaces are cleaned by for example wet etching. The wiring/interconnect in the upper metal wiring layer may be surrounded by or embedded in an insulating material, such as 222 in FIG. 2. Other parts above the upper metal wiring layer are then formed by using conventional processes, and thereby, a device, such as a logic device and a memory device, including MIM capacitors in the BEOL portion is manufactured.

FIGS. 6A-6K depict example processes of manufacturing an example apparatus 600 in a cross-sectional view according to some embodiments of the disclosure. The apparatus 600 may correspond to the apparatus 300 in FIG. 3. Sizes, positions, and the like of the components of the apparatus 600, however, may not be the same as those of the apparatus 300. The depicted processes correspond to at least part of the BEOL process after the FEOL process. The depicted processes show providing at least two MIM capacitors in the different (sub-)layer level between lower and upper metal wiring layers.

During the process shown in FIG. 6A, unlike the processes in FIGS. 5A-5D, a second metal film (or an upper metal film) 632 (e.g., 332 in FIG. 3) that will constitute an upper electrode of a MIM capacitor (e.g., 330b in FIG. 3) is formed after a first metal film (or a lower metal film) 631 (e.g., 331 in FIG. 3) and an insulating film 633 (e.g., 333 in FIG. 3) that will constitute a lower electrode and an insulator/capacitance film, respectively, of the same MIM capacitor are formed on the layered structure including an insulating film or layer 640/640a (e.g., 340/340a in FIG. 3), a barrier film or layer 750 (e.g., 350 in FIG. 3), an insulating layer 612 (e.g., 312 in FIG. 3), and a lower metal layer 610 (e.g., 310 in FIG. 3) including a wiring 611 (e.g., 311 in FIG. 3). The second metal film 632 may be formed by a deposition process, which may be the same or substantially the same as the deposition process used to form the second metal film 532 in FIG. 5D. The processes of forming the first metal film 631 and the insulating film 633 may be the same or substantially the same as those used to form the first metal film 531 and the insulating film 533a in FIG. 5A. The insulating film 633 in FIG. 6A is different from the insulating film 533a in FIG. 5A in that the thickness is initially made thicker to form the insulator/capacitance film of a high-voltage MIM capacitor (e.g., 330b in FIG. 3). Also, the formation and patterning of the insulating film 633 does not require application and removal of a resist material unlike the formation of the insulating film 533a in FIG. 5B.

As shown in FIG. 6B, a resist 690 is provided as a mask on at least part of the second metal film 632 (or a first film 632a thereof), and as shown in FIG. 6C, at least part of the second metal film 632 (including the first film 632a and a second film 632b thereof) and at least part of the insulating film 633 below the second metal film 632 that are not covered by the resist 690 are removed by, for example, photolithography and dry etching, to pattern the upper electrode and the insulator of the high-voltage MIM capacitor. The resist 690 is stripped, and a surface is cleaned by removing by-products of stripping and dry etching by, for example, wet etching. Unlike the processes in FIGS. 5B-5C which apply and remove the resist 590 to and from the insulating film 533a, the processes in FIGS. 6B-6C does not apply and remove the resist 690 directly to and from the insulating film 633.

As shown in FIG. 6D, a barrier film 634 (e.g., 334 in FIG. 3) is formed on the exposed surfaces of the second metal film 632 and the insulating film 633 by for example CVD. The barrier film 634 may prevent or mitigate metal diffusion. The barrier film 634 may also be used as an etching stop film for dry etching to form vias at a later process. The barrier film 634 may include, for example, SiCN, AlON, or AlOCN.

As shown in FIG. 6E, a resist 691 is provided as a mask on at least part of the barrier film 634, and as shown in FIG. 6F, at least part of the barrier film 634 and at least part of the first metal film 631 (including the first film 631a and a second film 631b thereof) that are not covered by the resist 691 are removed by, for example, photolithography and dry etching to pattern This patterns the lower electrode of the high-voltage MIM capacitor. The resist 691 is stripped, and a surface is cleaned by removing by-products of stripping and dry etching by, for example, wet etching. The high-voltage MIM capacitor is thus formed on the insulating layer 640/640a.

As shown in FIG. 6G, an insulating film 640 as another interlayer insulating film 640b (e.g., 340b in FIG. 3) is formed to cover the MIM capacitor and the first interlayer insulating film 640a by, for example, CVD or plasma-CVD. The surface of the second interlayer insulating film 640b is planarized by for example CMP. The insulating film 640/640b may include an oxide material, such as SiO2.

As shown in FIG. 6H, another MIM capacitor (MIM2, e.g., 330a in FIG. 3) is formed on the insulating film 640/640b using similar processes to those used for forming the first MIM capacitor (MIM1). The second MIM capacitor on the insulating film 640b is thus positioned higher than the first MIM capacitor on the insulating film 640a. During the processes to form the second, higher MIM capacitor, the insulator/capacitance film thereof is made thinner than that of the first, lower MIM capacitor. The second MIM capacitor thus becomes a low-voltage, high capacitance MIM capacitor. In a similar manner to the example of FIG. 5, the second MIM capacitor may be formed to partially overlap the first MIM capacitor. Furthermore, similarly to the example of FIG. 4, the thinner MIM capacitor including the thinner insulator and the thicker MIM capacitor including the thicker insulator may be switched. That is, the thinner MIM capacitor may be formed at a lower position and the thicker MIM capacitor can be formed at a higher position.

As shown in FIG. 6I, a further insulating film 640 as a third interlayer insulating film 640c (e.g., 340c in FIG. 3) is formed to cover the second, upper MIM capacitor and the second insulating film 640b by, for example, CVD or plasma-CVD. The surface of the third interlayer insulating film 640c is planarized by for example CMP. The insulating film 640/640c may include an oxide material, such as SiO2. All interlayer insulating films 640a, 640b and 640c may include the same oxide material.

Subsequently, in a similar manner to the processes shown in FIGS. 5K and 5L, vias are formed. As shown in FIG. 6J, openings 661 are formed by, for example, photolithography and dry etching, and as shown in FIG. 6K, the vias 660 (e.g., 360 in FIG. 3) are formed in the openings 661 by embedding therein a barrier metal material such as WN and a metal material such W by, for example, PVD, CVD, or ALD. One difference from the openings 561 and the vias 560 in FIGS. 5K and 5L may be that the size of each of the openings 661 and vias 660 in FIGS. 6J and 6K is adjusted for the position and the size of each of the MIM capacitors formed in the second and third interlayer insulating layer 640b and 640b. In some embodiments, vias may be provided below the lower electrode 631 of the MIM capacitor for coupling to the lower metal layer 610.

Finally, an upper metal wiring layer, such as 320 in FIG. 3 is formed by for example PVD, and a wiring/interconnect, such as 321 in FIG. 3, is patterned by for example photolithography and dry etching. The upper metal wiring layer may include TiN, Al, and Ti, and the wiring/interconnect may include Al. The surfaces are cleaned by for example wet etching. The wiring/interconnect may be surrounded by or embedded in an insulating material, such as 322 in FIG. 3. Other parts above the upper metal wiring layer are then formed by using conventional processes, and thereby, a device, such as a logic device and a memory device, including MIM capacitors in the BEOL portion is manufactured.

The above-described examples show two MIM capacitors; however, three or more MIM capacitors may be arranged between the first and second metal layers, and the height arrangement and/or the overlap arrangement may be appropriately determined based on device specification, device design, or the like.

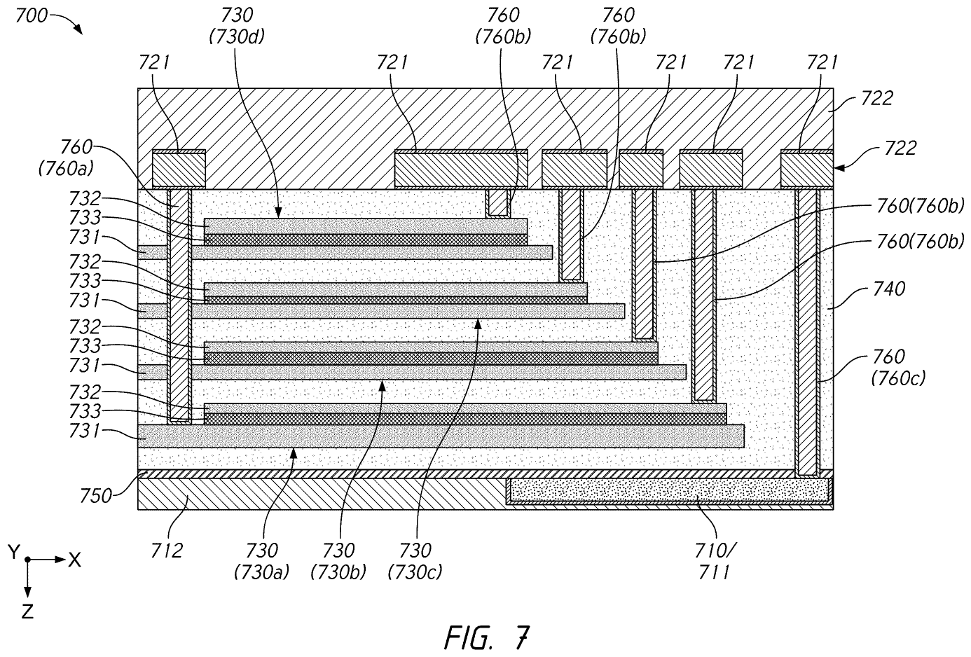

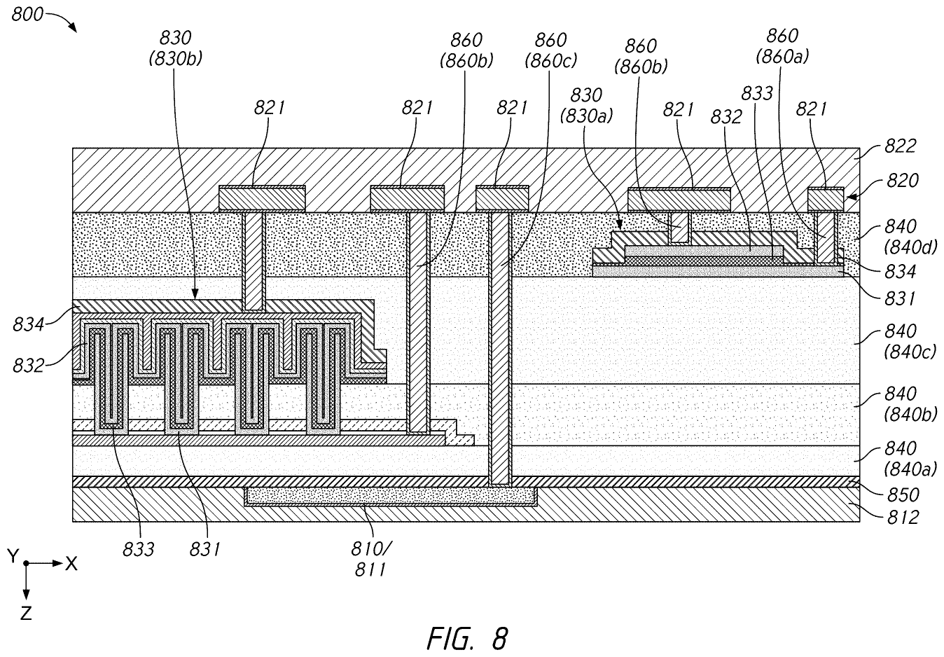

FIG. 7 depicts at least part of an example apparatus 700 in a cross-sectional view according to some embodiments of the disclosure. As shown in FIG. 7, the apparatus 700 includes two or more MIM capacitors 730 that are arranged on top of each other in an insulating layer 740 between first (lower) and second (upper) metal layers 710 and 720. In the example of FIG. 4, the MIM capacitor 430a partially overlaps the MIM capacitor 430b. In the example of FIG. 7, the upper MIM capacitors 730b-730d entirely or substantially entirely overlap the lowermost MIM capacitor 730a, creating multiple MIM capacitor layers. Each of the MIM capacitors 730 includes a first metal film 731 as a lower electrode, a second metal film 732 as an upper electrode, and an insulating film 733 as an insulator or a capacitance film between the first and second metal films 731 and 732. The MIM capacitors 730 have different types of capacitance film from one another. For example, all of or at least some of the insulating films 733 of the MIM capacitors 730 have the thickness different from one another. In the depicted example of FIG. 7, a barrier film on the second metal film 732 like the barrier film 434 in FIG. 4 is omitted. Vias 760 are arranged at appropriate positions to couple the first, lower metal film 731 (the lower electrode) or the second, upper metal film 732 (the upper electrode) to a corresponding wirings/interconnect 721 of the upper metal layer 720 embedded in an insulating film 722 or to couple between a wiring/interconnect 711 of the lower metal layer 710 embedded in an insulating film 712 and a corresponding wiring/interconnect 721 of the upper metal layer 720. For example, in the depicted example, a first via 760a extends through the insulating layer 740 and the first metal films 731 of the upper MIM capacitors 730b-730d and reaches the first metal film 731 of the lowermost MIM capacitor 730a from the corresponding wiring/interconnect 721. The first via 760a is shared by the first metal films 731 of the MIM capacitors 730a-730d. A second via 760b extends through the insulating layer 740 and reaches the second metal film 732 of the corresponding one of the MIM capacitors 730 from the corresponding one of the wiring/interconnects 721. A third via 760c extends through the insulating layer 740 and the barrier film 750 and reaches the corresponding wiring/interconnect 711 of the first metal layer 710 from the corresponding wiring/interconnect 721. The arrangement of the vias 760 is not limited to the depicted examples, and may be determined based on device specification, device design, or the like as appropriate. The apparatus 700 can further effectively increase the total amount of capacitance since a greater number of MIM capacitors can be stacked in the same area.

FIG. 8 depicts at least part of an example apparatus 800 in a cross-sectional view according to some embodiments of the disclosure. The apparatus 800 includes two MIM capacitors 830 between lower and upper metal layers 810 and 820 that are embedded in insulating materials 812 and 822, respectively. One (denoted as 830a) of the MIM capacitors 830 including first and second metal films 831 and 832, an insulating film 833 and a barrier film 834 is the same or substantially the same as the MIM capacitors 230a-430a or 230b-430b in FIGS. 2-4 whereas another one (denoted as 830b) of the MIM capacitors 830 is a three-dimension (3D) MIM capacitor. The 3D MIM capacitor 830b includes a first metal film 831 as a lower electrode including portions extending in the vertical (z-axis) direction in a fin-like structure, a second metal film 832 as an upper electrode along the first metal film 831 in the fin-like structure, and an insulating film 833 as a capacitance film between the first and second metal films 831 and 832. The 3D MIM capacitor 830b further includes a barrier and etching stopper film 834 on the second metal film 832. In some embodiments, there may be some other metal films between the second metal film 832 and the barrier film 834 and the second metal film 832. The fin-like structure of the 3D MIM capacitor 830b extends in the x-axis direction and also extends in the z-axis direction in multiple insulating films 840 (840b and 840c) above another insulating film 840 (840a). In the depicted example, the 3D MIM capacitor 830b is provided in a lower layer level than the MIM capacitor 830a embedded in still another insulating film 840 (840d) above the insulating film 840c. The 3D MIM capacitor 830b including the fin-like structure has a greater surface area and hence a greater capacitance than the MIM capacitor 830a. The thickness of the insulating film 833 of the 3D MIM capacitor 830b may be thinner or greater than that of the insulating film 833 of the MIM capacitor 830a. The apparatus 800 including the combination with the 3D MIM capacitor 830a can effectively increase the total capacitance.

According to the present embodiments described above, the MIM capacitors between the lower and upper metal wiring layers have the insulating films of different thickness. According to some embodiments, the MIM capacitors may include the insulating films different in thickness but with the same insulating material. According to some other embodiments, the MIM capacitors may have the insulating films different in both thickness and insulating material. According to some other embodiments, the MIM capacitors may have the insulating films of the same thickness but of different insulating materials. Such insulating materials may include a lower-k material and a higher-k material. The lower-k material may include, for example, SiO2 and Si3N4. The higher-k material may include, for example, zirconium dioxide (ZrO2), hafnium oxide (HfO2), and Al. The MIM capacitor with the insulating film of a lower-k material may be suitable for a higher voltage, and the MIM capacitor with the insulating film of a higher-k material may be suitable for a lower voltage and a higher capacitance. Such embodiments still are capable of including multiple MIM capacitors with different requirements in one device. According to still other embodiments, the MIM capacitors may have the insulating films of different thickness and different insulating materials.

DRAM is merely one example of a memory device, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a first metal layer and a second metal layer above the first metal layer in a back-end-of-line (BEOL) portion; and
a first metal-insulator-metal (MIM) capacitor and a second MIM capacitor between the first and the second metal layers in the BEOL portion, each of the first and second MIM capacitors including an insulating film between metal films, wherein
the insulating film of the first MIM capacitor has a first thickness, and
the insulting film of the second MIM capacitor has a second thickness greater than the first thickness.

2. The apparatus according to claim 1, wherein the first MIM capacitor is for a first voltage, and the second MIM capacitor is for a second voltage greater than the first voltage.

3. The apparatus according to claim 1, wherein the apparatus further comprises an insulating layer between the first and second metal layers, and the first and second MIM capacitors are in the insulating layer.

4. The apparatus according to claim 3, wherein the insulating layer may be an oxide layer.

5. The apparatus according to claim 1, wherein the first MIM capacitor and the second MIM capacitor are arranged at a same height position between the first and second metal layers.

6. The apparatus according to claim 1, wherein the first MIM capacitor and the second MIM capacitor are arranged at a first height position and a second height position, respectively, between the first and second metal layers, the first and second height positions are different from each other.

7. The apparatus according to claim 1, wherein the first MIM capacitor and the second MIM capacitor at least partially overlap with each other between the first and second metal layers.

8. The apparatus according to claim 1, wherein the first MIM capacitor and the second MIM capacitor are arranged on top of each other between the first and second metal layers.

9. The apparatus according to claim 1, wherein the insulating film of the first MIM capacitor includes a first insulating material, and the insulating film of the second MIM capacitor includes a second insulating material different from the first insulating material.

10. The apparatus according to claim 1, wherein the first and second MIM capacitors are coupled to at least one of the first and second metal layers.

11. The apparatus according to claim 1, further comprising a first via configured to couple the first MIM capacitor to a first metal wiring of the second metal layer; and a second via configured to couple the second MIM capacitor to a second metal wiring of the second metal layer.

12. An apparatus, comprising:
a first metal layer and a second metal layer above the first metal layer in a back-end-of-line (BEOL) portion;
an oxide layer between the first and second metal layers in the BEOL portion; and
a first metal-insulator-metal (MIM) capacitor and a second MIM capacitor in the oxide layer, each including an insulating film between metal films; and
a plurality of vias configured to couple the first MIM capacitor and the second MIM capacitor to at least one of the first metal layer or the second metal layer, wherein
the first MIM capacitor includes the insulting film having a first thickness for a first voltage, and
the second MIM capacitor includes the insulating film having a second thickness greater than the first thickness for a second voltage greater than the first voltage.

13. The apparatus according to claim 12, wherein the first MIM capacitor and the second MIM capacitor are arranged at a same height position between the first and second metal layers.

14. The apparatus according to claim 12, wherein the first MIM capacitor and the second MIM capacitor are arranged at a first height position and a second height position, respectively, between the first and second metal layers, the first and second height positions are different from each other.

15. The apparatus according to claim 12, wherein the first MIM capacitor and the second MIM capacitor at least partially overlap with each other between the first and second metal layers.

16. The apparatus according to claim 12, wherein the first MIM capacitor and the second MIM capacitor are arranged on top of each other between the first and second metal layers.

17. An apparatus, comprising a back-end-of-line (BEOL) portion above a semiconductor substrate, the portion including:
a first metal layer including a plurality of first wirings;
a second metal layer including a plurality of second wirings above the first metal layer; and
a plurality of metal-insulator-metal (MIM) capacitors between the first and second metal layers, each of the plurality of MIM capacitors coupled to at least one of the first metal layer or the second metal layer by one or more vias, wherein
a first MIM capacitor of the plurality of MIM capacitors includes a first insulating film of a first thickness for a first voltage, and
a second MIM capacitor of the plurality of MIM capacitors includes a second insulating film of a second thickness greater than the first thickness for a second voltage greater than the first voltage.

18. The apparatus according to claim 17, wherein the first MIM capacitor and the second MIM capacitor are arranged at a same height position between the first and second metal layers.

19. The apparatus according to claim 17, wherein the first MIM capacitor and the second MIM capacitor are arranged at a first height position and a second height position, respectively, between the first and second metal layers, the first and second height positions are different from each other.

20. The apparatus according to claim 17, wherein
the apparatus further comprises an insulating layer between the first and second metal layers,
one of the first and second MIM capacitors is positioned higher than and at least partially overlap another of the first and second MIM capacitors in the insulating layer.
